(19) United States
(12) Patent Application Publication
(10) Pub. No.: US 2020/0152425 A1
(43) Pub. Date: May 14, 2020

(54) SUBSTRATE PROCESSING CHAMBER COMPONENT ASSEMBLY WITH PLASMA RESISTANT SEAL

(71) Applicant: Applied Materials, Inc., Santa Clara, CA (US)

(72) Inventors: Vahid FIROUZDOR, Santa Clara, CA (US); Imad YOUSIF, San Jose, CA (US); Steven E. BABAYAN, Los Altos, CA (US); Rajinder DHINDSA, Pleasanton, CA (US); Changhun LEE, San Jose, CA (US); Khoi DOAN, San Jose, CA (US); John Anthony O'MALLEY, III, San Jose, CA (US)

(21) Appl. No.: 16/189,451

(22) Filed: Nov. 13, 2018

(51) Int. Cl. H01J 37/32; H01L 21/683; H01L 21/67; H01L 21/687

(52) U.S. Cl. CPC H01J 37/32495; H01J 37/32513; H01J 37/3211; H01L 21/6831; H01J 37/32697; H01J 2237/334; H01J 37/32724; H01L 21/6833; H01L 21/68735; H01L 21/67069; H01J 2237/166; H01L 21/67126

(57) ABSTRACT

Embodiments disclosed herein relate to a substrate processing chamber component assembly with plasma resistant seal. In one embodiment, the semiconductor processing chamber component assembly includes a first semiconductor processing chamber component, a second semiconductor processing component, and a sealing member. The sealing member has a body formed substantially from polytetrafluoroethylene (PTFE). The sealing member provides a seal between the first and second semiconductor processing chamber components. The body includes a first surface, a second surface, a first sealing surface, and a second sealing surface. The first surface is configured for exposure to a plasma processing region. The second surface is opposite the first surface. The first sealing surface and the second sealing surface extend between the first surface and the second surface. The first sealing surface contacts the first semiconductor processing chamber component. The second sealing surface contacts the second semiconductor processing chamber component.

### CROSS-REFERENCE TO RELATED APPLICATIONS

This application is a divisional application of the U.S. patent application Ser. No. 15/244,718, filed Aug. 23, 2016, which claims benefit of U.S. Provisional Application Ser. No. 62/362,436, filed Jul. 14, 2016, which is herein incorporated by reference in its entirety.

### BACKGROUND

### Field

Embodiments described herein generally relate to a substrate processing chamber component assembly with plasma resistant seal.

### Description of the Related Art

In the semiconductor industry, devices are fabricated by a number of manufacturing processes producing structures on an ever-decreasing size. Some manufacturing processes may generate particles, which frequently contaminate the substrate that is being processes, contributing to device defects. As device geometries shrink, susceptibility to defects increases and particle contaminant requirements become more stringent. Accordingly, as device geometries shrink, allowable levels of particle contamination may be reduced.

Additionally, to maintain vacuum levels within semiconductor processing systems, seals are used at various locations. Conventional seal materials typically are not highly resistant to erosion, and thus, have a tendency to erode quickly if exposed to direct or remote plasma with sufficient energy. This causes particle generation which in turn results in defects and high levels of contamination, and eventually results in a failed vacuum seal.

For more sensitive semiconductor applications, such as etching, erosive conditions are present inside the chamber due to the presence of corrosive gases and high energy plasma. Such an environment further limits the life of seals used with the processing chamber.

Therefore, there is a need for improved seals for use in substrate processing systems.

### SUMMARY

Embodiments disclosed herein generally relate to a substrate processing chamber component assembly with plasma resistant seal. In one embodiment, the semiconductor processing chamber component assembly includes a first semiconductor processing chamber component, a second semiconductor processing component, and a sealing member. The sealing member has a body formed substantially from polytetrafluoroethylene (PTFE). The sealing member provides a seal between the first and second semiconductor processing chamber components. The body includes a first surface, a second surface, a first sealing surface, and a second sealing surface. The first surface is configured for exposure to a plasma processing region. The second surface is opposite the first surface. The first sealing surface extends between the first surface and the second surface. The first sealing surface contacts the first semiconductor processing chamber component. The second sealing surface extends between the first surface and the second surface. The second sealing surface contacts the second semiconductor processing chamber component.

In another embodiment, a semiconductor processing chamber component assembly is disclosed herein. The semiconductor processing chamber component assembly includes an electrostatic chuck, a cooling base, and a sealing member. The sealing member has a body formed substantially from polytetrafluoroethylene (PTFE). The sealing member provides a seal between the electrostatic chuck and the cooling base. The body includes a first surface, a second surface, a first sealing surface, and a second sealing surface. The first surface is configured for exposure to a plasma processing region. The second surface is opposite the first surface. The first sealing surface extends between the first surface and the second surface. The first sealing surface contacts the electrostatic chuck. The second sealing surface extends between the first surface and the second surface. The second sealing surface contacts the cooling base.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a sectional side view illustrating a processing chamber having one or more sealing members, according to one embodiment.

FIG. 2 is an enlarged view of the sealing member of FIG. 1, according to one embodiment.

FIG. 3 is an enlarged view of the sealing member of FIG. 2 positioned between a first processing chamber component and a second processing chamber component, according to one embodiment.

FIG. 4 is an enlarged view of the sealing member of FIG. 1, according to one embodiment.

FIG. 5 is an enlarged view of the sealing member of FIG. 1, according to one embodiment.

For clarity, identical reference numerals have been used, where applicable, to designate identical elements that are common between figures. Additionally, elements of one embodiment may be advantageously adapted for utilization in other embodiments described herein.

### DETAILED DESCRIPTION

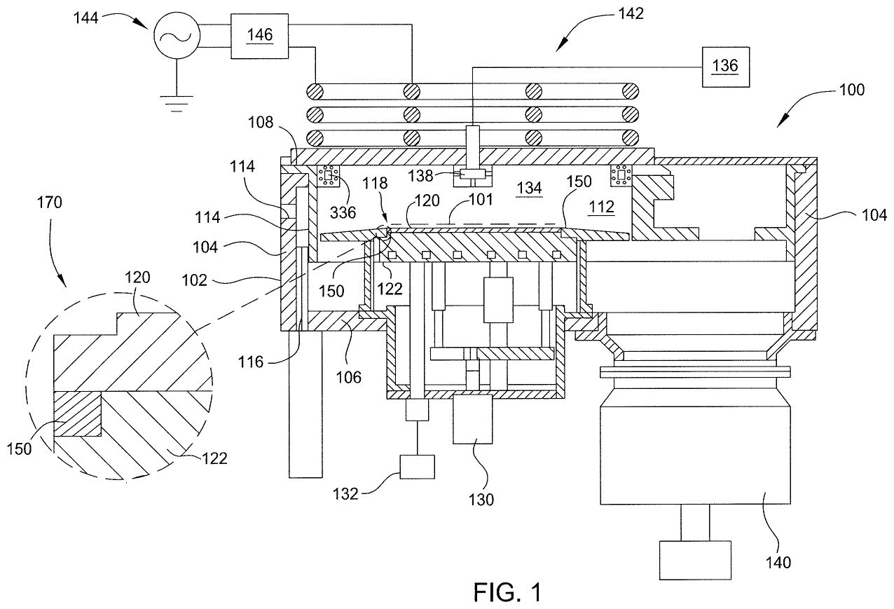

FIG. 1 is a sectional side view illustrating a processing chamber 100 having sealing members 150, according to one embodiment. As shown, the processing chamber 100 is an etch chamber, capable of etching a substrate. Examples of processing chambers that may be adapted to benefit from the disclosure are Sym3® Processing Chamber, C3® Processing Chamber, and Mesa™ Processing Chamber, commercially available from Applied Materials, Inc, located in Santa Clara, Calif. It is contemplated that other processing chambers including those from other manufacturers may be adapted to benefit from the disclosure.

The processing chamber 100 may be used for various plasma processes. In one embodiment, the processing chamber 100 may be used to perform dry etching with one or more etching agents. For example, the processing chamber may be used for ignition of plasma from a precursor CₓF_{y} (where x and y can be different allowed combinations, O₂, NF₃, or combinations thereof. Embodiments of the present disclosure may also be used in etching chromium for photomask applications, etching a profile, such as deep trench and through silicon vias (TSV), in a silicon substrate having oxide and metal layers disposed on the substrate 101.

The processing chamber 100 includes a chamber body 102 having sidewalls 104, a bottom 106, and a chamber lid 108. The sidewalls 104, bottom 106, and chamber lid 108 define an interior volume 110. The processing chamber 100 further includes a liner 112 disposed in the interior volume 110. The liner 112 is configured to prevent the sidewalls 104 from damage and contamination from the processing chemistry and/or processing by-products. A slit valve door opening 114 is formed through the sidewall 104. The slit valve door opening 114 is configured to allow passage of substrates and substrate transfer mechanism. A slit valve door 116 selectively opens and closes the slit valve door opening 114.

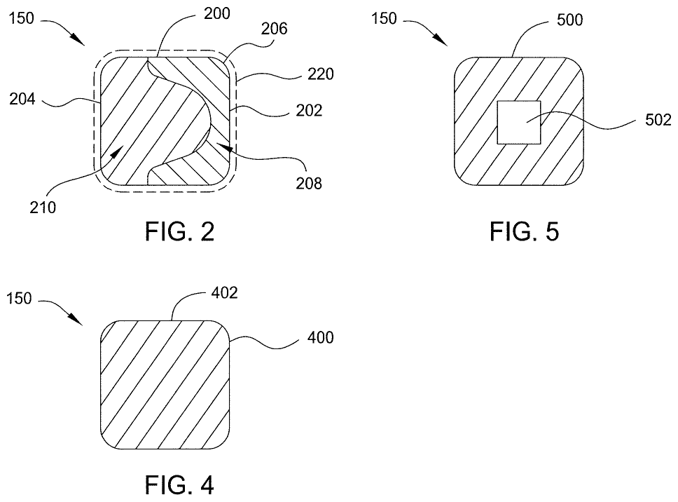

The processing chamber 100 further includes an electrostatic chuck 118 disposed in the interior volume 110. The electrostatic chuck 118 is movably or fixedly positioned in the processing chamber 100. The electrostatic chuck 118 is configured to support a substrate 101 during processing. The electrostatic chuck 118 includes a chuck body 120 and a chuck base 122. The chuck body 120 and chuck base 122 may define a semiconductor processing chamber component assembly 170. The chuck body 120 is secured to the chuck base by a bonding material 124. The electrostatic chuck 118 further includes one or more sealing members 150. The one or more sealing members 150 may be disposed around the bonding material 124 to protect the bonding material 124 from the processing environment. The one or more sealing members 150 are discussed in more detail below, in conjunction with FIGS. 2-5.

The chuck body 120 may include one or more through holes (not shown) formed therethrough. The through holes are configured to allow lift pins 128 to pass therethrough to space the substrate 101 from the surface of the electrostatic chuck 118. A lift 130 is configured to raise and lower lift pins 128 relative to the electrostatic chuck 118 during processing and loading/unloading the substrate 101. The electrostatic chuck 118 may be coupled to a bias power source 132 for generating chucking force to secure the substrate 101 on the electrostatic chuck.

One or more processing gases may be supplied to a plasma processing region 134 from a gas source 136 via an inlet 138. The processing chamber 100 may further include a vacuum pump 140 in fluid communication with the plasma processing region 134. The vacuum pump 140 is configured to pump the plasma processing region 134 and maintain a low pressure environment.

The processing chamber 100 may further include an antenna assembly 142 disposed exterior to the chamber lid 108. The antenna assembly 142 may be coupled to a radio-frequency (RF) power source 144 through a matching network 146. During processing, the antenna assembly 142 is energized with RF power provided by the power source 144 to ignite a plasma of processing gases within plasma processing region 134 and to maintain the plasma during processing of the substrate 101.

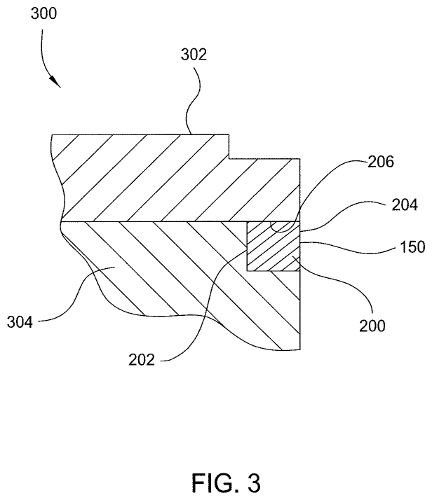

FIGS. 2 and 3 are enlarged views of the sealing member 150, according to one embodiment. The sealing member 150 generally includes a body 200. The body 200 includes a first surface 202, a second surface 204, and a sealing surface 206. The first surface 202 is exposed to a plasma processing region of the processing chamber 100. The second surface 204 is opposite the first surface. In one embodiment, the second surface 204 is exposed to a component of the substrate processing chamber 100. The sealing surface 206 extends between the first surface 202 and the second surface 204. The sealing surface 206 is configured to contact a first component of the processing chamber 100. For example, the sealing surface 206 is configured to contact the chuck body 120 and an opposite side contacting the chuck base 122 in the processing chamber 100, such that a seal is formed between the chuck body 120 and the chuck base 122. In addition to being used between the chuck body 120 and the chuck base 122 of the electrostatic chuck 118, the sealing members 150 may be used in several other locations in the processing chamber 100. For example, the sealing member 150 may be used in the chamber lid 108, the liner 112, the showerhead, nozzle, cathode, or other suitable locations in the processing chamber 100. As shown in FIG. 3, generally, the sealing member 150 may be positioned between a first processing chamber component 302 and a second processing chamber component 304. Collectively, the sealing member 150, the first processing chamber component 302, and the second processing chamber component 304 may define a semiconductor processing chamber component assembly 300.

Generally, the body 200 may be formed at least partially from polytetrafluoroethylene (PTFE). For example, the body 200 may include a first portion 208 and a second portion 210. The first portion 208 includes at least the first surface 202. The first portion 208 may be formed from PTFE. The PTFE in the first portion 208 has a higher erosion resistance compared to conventional FKM polymers and FFKM polymers used to form sealing members 150. Thus, the first surface 202 exposed to the plasma processing region 134 is formed from a higher erosion resistance material and will withstand being exposed to the plasma better than conventional FKM and FFKM polymers.

Additionally, conventional sealing members formed from FKM polymers and FFKM polymers typically compress about 15%-20% in size, or about 0.9 inches to 1 inch. The first portion 208 formed from PTFE only compresses about 1% in size, or about 0.1 inches to 0.2 inches. The compression of the PTFE is due to the vacuum compression force of the processing chamber 100. The high compression force results in an enhanced seal for the PTFE sealing member 150. For example, a compression force of up to 20-30 KN can be achieved in some processing chamber 100. The second portion 210 may be formed from an FKM polymer or an FFKM polymer. For example, the second portion 210 may be formed from SiC, TiO₂, Ba₂SO₄, MgO, or other suitable material. The sealing surface 206 may be comprised partially of the first portion 208 and the second portion 210. Thus, the first portion 208 compresses less than the second portion 210 when in contact with the first component of the processing chamber. Therefore, when the sealing member 150 having body 200 is positioned between the first processing chamber component and the second processing chamber component, the first processing chamber component will be raised slightly higher on the side contacting the first portion 208 of the body 200 compared to the side of the first processing chamber component contacting the second portion 210 of the body 200. For example, the body 200 may compress about 10-20 mm on the side contacting the first portion 208 of the body 200 and the body 200 may compress about 15-25 mm on the side contacting the second portion 210 of the body 200.

In one embodiment, the body 200 may be quadrilaterally shaped to increase the surface area that contacts the component of the processing chamber 100. For example, the body 200 may have a rectangular shape that allows for a greater surface area of the sealing surface 206 to contact the first component of the processing chamber 100. By increasing the surface area of the first component that the sealing surface 206 comes into contact with, an enhanced seal is formed between the sealing member 150 and the first component. Additionally, the body 200 may further include a surface finish 220. The surface finish 220 may be in the range of 1-30 pinches. The surface finish 220 results in a smoother surface for the body 200, which aids in achieving an enhanced seal with a processing chamber component.

FIG. 4 is an enlarged view of the sealing member 150, according to another embodiment. The sealing member 150 generally includes a body 400. The body 400 includes at least a sealing surface 402. The body 400 may be formed substantially from PTFE. In one embodiment, the body 400 is formed purely from PTFE. In another embodiment, the body 400 is formed substantially from PTFE and combined with an additive. For example, adequate additives may include, but are not limited to, SiC and polyamide.

FIG. 5 is an enlarged view of the sealing member 150, according to another embodiment. The sealing member 150 generally includes a body 500 formed substantially from PTFE. The body 500 may be substantially hollow. For example, the body 500 may be about 50% more hollow than the body 200 and the body 400 in FIGS. 2-4. The hollow body 500 is configured to increase the elastic properties of the PTFE material. In some embodiments, the sealing member 150 may include an elastic material injected into a hollow core 502 of the body 500. For example, the elastic material may be an FKM or FFKM polymer. The elastic material injected in the hollow core 502 is configured to increase the elastic properties of the body 500.

While the foregoing is directed to specific embodiments, other and further embodiments may be devised without departing from the basic scope thereof, and the scope thereof is determined by the claims that follow.

What is claimed is:

1. A semiconductor processing chamber component assembly, comprising:
a first semiconductor processing chamber component;
a second semiconductor processing chamber component; and
a sealing member providing a seal between the first and second semiconductor processing chamber components, the sealing member having a body including a first portion formed substantially from PTFE and a second portion formed substantially from an FKM or FFKM polymer, the body further comprising:
a first side configured for exposure to a plasma processing region;
a second side opposite the first side;
a first sealing surface extending between the first side and the second side, the first sealing surface contacting the first semiconductor processing chamber component; and
a second sealing surface extending between the first side and the second side, the second sealing surface contacting the second semiconductor processing chamber component, wherein the first sealing surface, the second sealing surface, the first side, and the second side include a surface finish in the range of 1-30 pinches.

2. The semiconductor processing chamber component assembly of claim 1, wherein the sealing surface is comprised of the first portion and the second portion.

3. The semiconductor processing chamber component assembly of claim 1, wherein the first portion formed substantially from PTFE includes a polymer additive.

4. The semiconductor processing chamber component assembly of claim 1, wherein the body is quadrilaterally shaped.

5. The semiconductor processing chamber component assembly of claim 1, wherein the first portion is formed purely from PTFE.

6. The semiconductor processing chamber component assembly of claim 1, wherein the first portion compresses less than the second portion when in contact with the first semiconductor processing chamber component.

7. The semiconductor processing chamber component assembly of claim 1, wherein the first semiconductor processing chamber component is an electrostatic chuck body.

8. The semiconductor processing chamber component assembly of claim 7, wherein the second semiconductor processing chamber component is a cooling base.

9. A semiconductor processing chamber component assembly, comprising:
an electrostatic chuck;
a cooling base; and
a sealing member providing a seal between the electrostatic chuck and the cooling base, the sealing member having a body including a first portion formed substantially from PTFE and a second portion formed substantially from an FKM or FFKM polymer, the body further comprising:
a first side configured for exposure to a plasma processing region;
a second side opposite the first side;
a first sealing surface extending between the first side and the second side, the first sealing surface contacting the electrostatic chuck; and
a second sealing surface extending between the first side and the second side, the second sealing surface contacting the cooling base, wherein the first sealing surface, the second sealing surface, the first side, and the second side include a surface finish in the range of 1-30 pinches.

10. The semiconductor processing chamber component of claim 9, wherein the second portion is formed from one of SiC, TiO2, Ba2SO4, MgO.

11. The semiconductor processing chamber component assembly of claim 9, wherein the sealing surface is comprised of the first portion and the second portion.

12. The semiconductor processing chamber component assembly of claim 9, wherein the body compresses about 0.1 inches.

13. The semiconductor processing chamber component assembly of claim 9, wherein the first portion formed substantially from PTFE includes a polymer additive.

14. The semiconductor processing chamber component assembly of claim 9, wherein the body is quadrilaterally shaped.

15. The semiconductor processing chamber component assembly of claim 9, wherein the body is formed purely from PTFE.
